(19) United States
(12) Patent Application Publication
(10) Pub. No.: US 2025/0316231 A1
(43) Pub. Date: Oct. 9, 2025

(54) DISPLAY DEVICE

(71) Applicant: Samsung Display Co., LTD., Yongin-si (KR)

(72) Inventors: Jun Hyun PARK, Yongin-si (KR); Young Wan SEO, Yongin-si (KR); So Il YOON, Yongin-si (KR)

(21) Appl. No.: 19/031,667

(22) Filed: Jan. 18, 2025

(30) Foreign Application Priority Data
Apr. 9, 2024 (KR) 10-2024-0048007

(51) Int. Cl. G09G 3/3233; H10K 59/121; H10K 59/131

(52) U.S. Cl. CPC G09G 3/3233; H10K 59/1213; H10K 59/131; G09G 2300/0426; G09G 2300/0819; G09G 2300/0842; G09G 2300/0861; G09G 2310/08; G09G 2330/021

(57) ABSTRACT

A display device includes a light emitting element disposed on a substrate, a first transistor configured to control a driving current flowing to a first node that is a first electrode 5 of the light emitting element, a second transistor configured to initialize the first node to a first initialization voltage based on a first gate signal having a first gate low voltage, and a gate low voltage line configured to supply a second gate low voltage lower than the first gate low voltage to a bias electrode of the second transistor.

This application claims priority to Korean Patent Application No. 10-2024-0048007, filed on Apr. 9, 2024, and all the benefits accruing therefrom under 35 U.S.C. § 119, the content of which in its entirety is herein incorporated by reference.

### BACKGROUND

### 1. Technical Field

Embodiments of the invention relate to a display device.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display device may display an image without a backlight unit providing light to a display panel because each of pixels of the display panel includes light emitting elements that may emit light by themselves.

The display device includes a plurality of pixels, data lines and gate lines connected to the plurality of pixels, a data driver supplying data voltages to the data lines, and a gate driver supplying gate signals to the gate lines. The data driver and the gate driver may drive the plurality of pixels according to a predetermined frequency.

### SUMMARY

Embodiments of the invention provide a display device capable of reducing power consumption of a pixel circuit.

An embodiment of the invention provides a display device including a light emitting element disposed on a substrate, a first transistor configured to control a driving current flowing to a first node that is a first electrode of the light emitting element, a second transistor configured to initialize the first node to a first initialization voltage based on a first gate signal having a first gate low voltage, and a gate low voltage line configured to supply a second gate low voltage lower than the first gate low voltage to a bias electrode of the second transistor.

In an embodiment, the display device may further include a third transistor configured to supply a data voltage to a second node based on a second gate signal, the second node being a first electrode of the first transistor, a fourth transistor electrically connecting a third node and a fourth node to each other based on a third gate signal, the third node being a second electrode of the first transistor and the fourth node being a gate electrode of the first transistor, and a fifth transistor configured to initialize the fourth node to a second initialization voltage based on a fourth gate signal.

In an embodiment, the display device may further include a driving voltage line configured to supply a driving voltage, a sixth transistor electrically connecting the driving voltage line and the second node to each other based on an emission signal, and a seventh transistor electrically connecting the third node and the first node to each other based on the emission signal.

In an embodiment, the driving voltage line and the gate low voltage line may be disposed at a lower layer of a semiconductor region of the second transistor.

In an embodiment, the display device may further include a bottom metal layer disposed on the substrate and including the driving voltage line and the gate low voltage line, a first active layer disposed on the bottom metal layer and including semiconductor regions of the first and second transistors, a first gate layer disposed on the first active layer and including gate electrodes of the first and second transistors, a second active layer disposed on the first gate layer and including a semiconductor region of the fourth transistor, and a second gate layer disposed on the second active layer and including a gate electrode of the fourth transistor.

In an embodiment, the display device may further include an eighth transistor configured to supply a bias voltage to the second node based on the first gate signal.

In an embodiment, the fourth transistor and the fifth transistor each may include an oxide-based semiconductor region, and the second transistor may include a silicon-based semiconductor region.

In an embodiment, the second transistor, the fourth transistor, and the fifth transistor each may include a silicon-based semiconductor region. The gate low voltage line may be configured to supply the second gate low voltage to a bias electrode of the fifth transistor.

In an embodiment, the display device may further include a plurality of stages configured to supply the first to fourth gate signals. The gate low voltage line may be configured to supply the second gate low voltage to the plurality of stages.

In an embodiment, the display device may further include a plurality of stages configured to supply the first to fourth gate signals. The gate low voltage line may be insulated from the plurality of stages.

An embodiment of the invention provides a display device including a driving voltage line disposed on a substrate, a first transistor disposed on the driving voltage line, a light emitting element configured to receive a driving current flowing through the first transistor, a second transistor configured to initialize a first node to a first initialization voltage based on a first gate signal, the first node being a first electrode of the light emitting element, and a gate low voltage line disposed at the same layer as the driving voltage line and electrically connected to a bias electrode of the second transistor.

A low level of the first gate signal may correspond to a first gate low voltage, and the gate low voltage line may be configured to supply a second gate low voltage lower than the first gate low voltage.

In an embodiment, the display device may further include a third transistor configured to supply a data voltage to a second node based on a second gate signal, the second node being a first electrode of the first transistor, a fourth transistor electrically connecting a third node and a fourth node to each other based on a third gate signal, the third node being a second electrode of the first transistor and the fourth node being a gate electrode of the first transistor, and a fifth transistor configured to initialize the fourth node to a second initialization voltage based on a fourth gate signal.

In an embodiment, the display device may further include a sixth transistor electrically connecting the driving voltage line and the second node to each other based on an emission signal, a seventh transistor electrically connecting the third node and the first node to each other based on the emission signal, and an eighth transistor configured to supply a bias voltage to the second node based on the first gate signal.

In an embodiment, the bias electrode of the second transistor may correspond to a portion of the gate low voltage line and may overlap a semiconductor region and a gate electrode of the second transistor in a plan view.

In an embodiment, the display device may further include a bottom metal layer including the driving voltage line and the gate low voltage line, a first active layer disposed on the bottom metal layer and including semiconductor regions of the first and second transistors, a first gate layer disposed on the first active layer and including gate electrodes of the first and second transistors, a second active layer disposed on the first gate layer and including a semiconductor region of the fourth transistor, and a second gate layer disposed on the second active layer and including a gate electrode of the fourth transistor. The fifth transistor may include an oxide-based semiconductor region, and the second transistor includes a silicon-based semiconductor region. The fifth transistor and the second transistor each may include a silicon-based semiconductor region. The gate low voltage line may be configured to supply the second gate low voltage to a bias electrode of the fifth transistor.

In an embodiment, the display device may further include a plurality of stages configured to supply the first to fourth gate signals. The gate low voltage line may be electrically connected to the plurality of stages.

In an embodiment, the display device may further include a plurality of stages configured to supply the first to fourth gate signals. The gate low voltage line may be insulated from the plurality of stages.

An embodiment of the invention provides a display device including a light emitting element disposed on a substrate, a first transistor configured to control a driving current flowing to the light emitting element, a second transistor configured to initialize a gate electrode of the first transistor to a first initialization voltage based on a first gate signal having a first gate low voltage, and a gate low voltage line configured to supply a second gate low voltage lower than the first gate low voltage to a bias electrode of the second transistor.

In embodiments according to the invention, it is possible to effectively reduce power consumption of a pixel circuit by supplying a first gate low voltage to a gate electrode of an initialization transistor initializing a first electrode of a light emitting element or initializing a gate electrode of a driving transistor and supplying a second gate low voltage lower than the first gate low voltage to a bias electrode of the initialization transistor to reduce a threshold voltage of the initialization transistor.

### BRIEF DESCRIPTION OF THE DRAWINGS

These and/or other features of the invention will become apparent and more readily appreciated from the following description of the embodiments, taken in conjunction with the accompanying drawings, in which:

FIG. 1 is a perspective view illustrating a display device according to an example embodiment;

FIG. 2 is a block diagram illustrating the display device according to an example embodiment;

FIG. 3 is a cross-sectional view illustrating the display device according to an example embodiment;

FIG. 4 is a circuit diagram illustrating a pixel of the display device according to an example embodiment;

FIG. 5 is a timing diagram illustrating variable frequency driving of the display device according to an example embodiment;

FIG. 6 is a waveform diagram of signals supplied to the pixel illustrated in FIG. 4;

FIG. 7 is a cross-sectional view illustrating a portion of the pixel of FIG. 4;

FIG. 8 is a circuit diagram illustrating a pixel of a display device according to another example embodiment;

FIG. 9 is a diagram illustrating an example of a driving voltage line and a gate low voltage line in the display device according to an example embodiment;

FIG. 10 is a diagram illustrating another example of a driving voltage line and a gate low voltage line in the display device according to an example embodiment;

FIG. 11 is a layout diagram illustrating a portion of the pixel in the display device according to an example embodiment;

FIG. 12 is a cross-sectional view taken along line I-I′ of FIG. 11;

FIG. 13 is a circuit diagram illustrating an example of a stage of a gate driver in the display device according to an example embodiment; and

FIG. 14 is a circuit diagram illustrating another example of a stage of a gate driver in a display device according to another example embodiment.

### DETAILED DESCRIPTION

Embodiments of the invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification. In the attached drawing figures, the thickness of layers and regions is exaggerated for clarity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will also be understood that when a layer is referred to as being “on” another layer or substrate, it can be directly on the other layer or substrate, or intervening layers may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” “At least one of A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the invention will be described in detail with reference to the accompanying drawings.

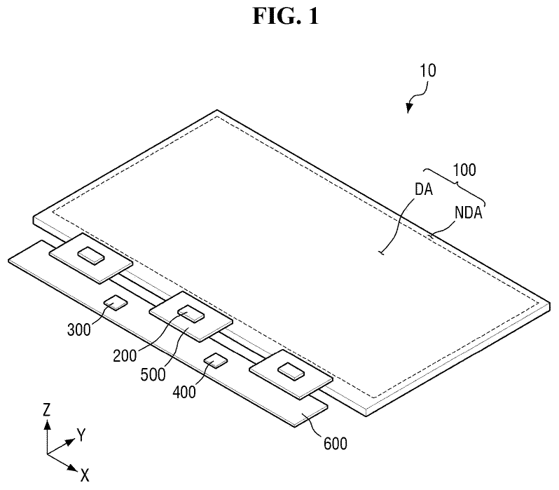

FIG. 1 is a perspective view illustrating a display device according to an example embodiment.

Referring to FIG. 1, a display device 10 is a device that displays a moving image or a still image, and may be used as a display screen of various products such as televisions, laptop computers, monitors, billboards, and Internet of Things (“IoT”) as well as portable electronic devices such as mobile phones, smartphones, tablet personal computers (“PCs”), smart watches, watch phones, mobile communication terminals, electronic notebooks, electronic books, portable multimedia players (“PMPs”), navigation devices, and ultra mobile PCs (“UMPCs”).

The display device 10 may include a display panel 100, data drivers 200, a timing controller 300, a power supply unit 400, data circuit boards 500, and a control circuit board 600.

The display panel 100 may have a rectangular shape, in a plan view, having long sides in an X-axis direction and short sides in a Y-axis direction crossing the X-axis direction. A corner where the long side in the X-axis direction and the short side in the Y-axis direction meet may be rounded with a predetermined curvature or may be right-angled. A shape of the display panel 100 in a plan view is not limited to the rectangular shape, and may be other polygonal shapes, a circular shape, or an elliptical shape. The display panel 100 may be formed to be flat but is not limited thereto. For another example, the display panel 100 may include curved surface portions formed at left and right ends thereof and having a constant curvature or a variable curvature. The display panel 100 may be flexibly formed to be curved, bent, folded, or rolled. As used herein, the ‘plan view’ is a view in a thickness direction (i.e., Z-axis direction) of the display device 10.

The display panel 100 may include a display area DA displaying an image and a non-display area NDA disposed around the display area DA. The display area DA may occupy most of the area of the display panel 100. The display area DA may be disposed at the center of the display panel 100. The display area DA may include a plurality of pixels displaying the image.

Each of the plurality of pixels may include a light emitting element emitting light. The light emitting element may include at least one of an organic light emitting diode (“LED”) including an organic light emitting layer, a quantum dot LED including a quantum dot light emitting layer, an inorganic LED including an inorganic semiconductor, and a micro LED, but is not limited thereto.

The non-display area NDA may be disposed adjacent to the display area DA. The non-display area NDA may be an area outside the display area DA. The non-display area NDA may be disposed to surround the display area DA. The non-display area NDA may be an edge area of the display panel 100.

The non-display area NDA may include a gate driver, fan-out lines, and pad portions. The gate driver may supply gate signals to gate lines of the display area DA. The fan-out lines may electrically connect the data driver 200 and data lines of the display area DA to each other. The pad portions may be electrically connected to the data circuit boards 500. For example, the pad portions may be disposed at an edge of one side of the display panel 100, and the gate driver may be disposed at an edge of the other side of the display panel 100 adjacent to the edge of one side of the display panel 100, but the present disclosure is not limited thereto.

The data driver 200 may output signals and voltages for driving the display panel 100. The data driver 200 may supply data voltages to the data lines. The data driver 200 may supply source voltages to power lines and supply gate control signals to the gate driver. The data driver 200 may be formed as an integrated circuit (“IC”) and mounted on the data circuit board 500 in a chip on film (“COF”) manner. As another example, the data driver 200 may be mounted on the non-display area NDA of the display panel 100 in a chip on glass (“COG”) manner, a chip on plastic (“COP”) manner, or an ultrasonic bonding manner.

The timing controller 300 may be mounted on the control circuit board 600 and may receive digital video data and a timing synchronization signal supplied from a display driving system or a graphic device through a user connector provided on the control circuit board 600. The timing controller 300 may align the digital video data to be suitable for a pixel arrangement structure based on the timing synchronization signal and may supply the aligned digital video data to the data driver 200. The timing controller 300 may generate data control signals and gate control signals based on the timing synchronization signals. The timing controller 300 may control supply timings of the data voltages of the data driver 200 based on the data control signals, and control supply timings of the gate signals of the gate driver based on the gate control signals.

The power supply unit 400 may be mounted on the control circuit board 600 and may supply source voltages to the display panel 100 and the data driver 200. For example, the power supply unit 400 may generate a driving voltage, a common voltage, an initialization voltage, a bias voltage, a gate high voltage, a gate low voltage, or a reference voltage. The power supply unit 400 may supply the source voltages to drive the plurality of pixels and the data driver 200.

The data circuit boards 500 may be disposed on the pad portions disposed at the edge of one side of the display panel 100. The data circuit boards 500 may be attached to the pad portions using conductive adhesive members such as anisotropic conductive films. The data circuit boards 500 may be electrically connected to signal lines of the display panel 100 through the anisotropic conductive films. The display panel 100 may receive the data voltages and the source voltages through the data circuit boards 500. For example, the data circuit board 500 may be a flexible printed circuit board, a printed circuit board, or a flexible film such as a chip on film.

The control circuit board 600 may be attached to the data circuit boards 500 using an anisotropic conductive film, a low-resistance and high-reliability material such as a self-assembly anisotropic conductive paste (“SAP”), or the like. The control circuit board 600 may be electrically connected to the data circuit boards 500. The control circuit board 600 may be a flexible printed circuit board or a printed circuit board.

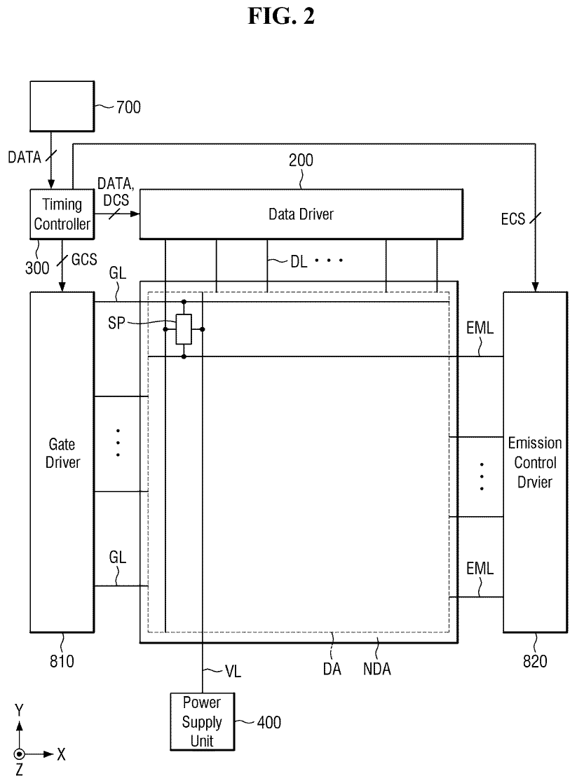

FIG. 2 is a block diagram illustrating the display device according to an example embodiment.

Referring to FIG. 2, the display panel 100 may include a display area DA and a non-display area NDA.

The display area DA may include a plurality of pixels SP and voltage lines VL, gate lines GL, emission control lines EML, and data lines DL that are connected to the pixels SP.

Each of the plurality of pixels SP may be connected to the gate line GL, the data line DL, the emission control line EML, and the voltage line VL. Each of the plurality of pixels SP may include a transistor, a capacitor, and a light emitting element.

The gate lines GL may extend in the X-axis direction and may be spaced apart from each other in the Y-axis direction crossing the X-axis direction. The gate line GL may sequentially supply gate signals to the plurality of pixel SP.

The emission control lines EML may extend in the X-axis direction and may be spaced apart from each other in the Y-axis direction. The emission control lines EML may sequentially supply emission signals to the plurality of pixels SP.

The data lines DL may extend in the Y-axis direction and may be spaced apart from each other in the X-axis direction. The data lines DL may supply data voltages to the plurality of pixels SP. The data voltage may determine luminance of each of the plurality of pixels SP.

The voltage lines VL may extend in the Y-axis direction and may be spaced apart from each other in the X-axis direction. The voltage lines VL may supply source voltages to the plurality of pixels SP. The source voltage may include at least one of a driving voltage, a common voltage, an initialization voltage, a bias voltage, a gate high voltage, a gate low voltage, and a reference voltage. For example, the driving voltage may be a high potential voltage for driving the light emitting element of the pixel SP, and the common voltage may be a low potential voltage for driving the light emitting element of the pixel SP.

The data driver 200 may convert digital video data DATA into analog data voltages and supply the analog data voltages to the data lines DL through fan-out lines. Gate signals of a gate driver 810 may select pixels SP to which the data voltages are supplied, and the selected pixels SP may receive the data voltages through the data lines DL.

The timing controller 300 may receive the digital video data DATA and timing signals from a graphic device 700. For example, the graphic device 700 may be a graphic card of the display device 10 but is not limited thereto. The timing controller 300 may control an operation timing of the data driver 200 by generating a data control signal DCS based on the timing signal and supplying the data control signal DCS to the data driver 200 in another embodiment. The timing controller 300 may supply the digital video data DATA to the data driver 200. The timing controller 300 may control an operation timing of the gate driver 810 by generating a gate control signal GCS based on the timing signal and supplying the gate control signal GCS to the gate driver 810. The timing controller 300 may control an operation timing of an emission control driver 820 by generating an emission control signal ECS based on the timing signal and supplying the emission control signal ECS to the emission control driver 820. The timing controller 300 may vary a driving frequency of the display panel 100 based on an input frequency of the digital video data DATA of the graphic device 700.

The power supply unit 400 may be disposed on the control circuit board 600 and may supply source voltages to the data driver 200 and the display panel 100. The power supply unit 400 may generate a driving voltage and supply the driving voltage to a driving voltage line, and may generate a common voltage and supply the common voltage to a common electrode common to the light emitting elements of the pixels. The power supply unit 400 may generate an initialization voltage and supply the initialization voltage to an initialization voltage line and may generate a bias voltage and supply the bias voltage to a bias voltage line. The power supply unit 400 may generate a gate high voltage and supply the gate high voltage to a gate high voltage line, may generate a gate low voltage and supply the gate low voltage to a gate low voltage line, and may generate a reference voltage and supply the reference voltage to a reference voltage line.

The gate driver 810 may be disposed outside one side of the display area DA or on one side of the non-display area NDA, and the emission control driver 820 may be disposed outside the other side of the display area DA or on the other side of the non-display area NDA, but the present disclosure is not limited thereto. As another example, the gate driver 810 and the emission control driver 820 may be disposed on either one side or the other side of the non-display area NDA.

The gate driver 810 may include a plurality of transistors generating gate signals based on the gate control signal GCS. The emission control driver 820 may include a plurality of transistors generating emission signals based on the emission control signal ECS. For example, the transistors of the gate driver 810 and the transistors of the emission control driver 820 may be formed at the same layer as the transistor of each of the pixels SP. The gate driver 810 may supply the gate signals to the gate lines GL, and the emission control driver 820 may supply the emission signals to the emission control lines EML.

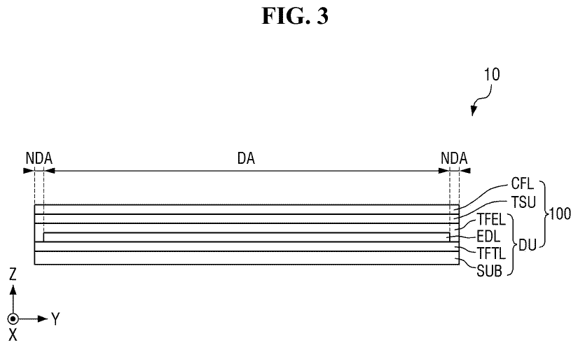

FIG. 3 is a cross-sectional view illustrating the display device according to an example embodiment.

Referring to FIG. 3, the display panel 100 may include a display unit DU, a touch sensing unit TSU, and a color filter layer CFL. The display unit DU may include a substrate SUB, a transistor layer TFTL, a light emitting element layer EDL, and an encapsulation layer TFEL.

The substrate SUB may be a base substrate or a base member. The substrate SUB may be a flexible substrate that may be bent, folded, and rolled. As an example, the substrate SUB may include a polymer resin such as polyimide (“PI”) but is not limited thereto. As another example, the substrate SUB may include a glass material or a metal material.

The transistor layer TFTL may be disposed on the substrate SUB. The transistor layer TFTL may include a plurality of transistors constituting pixel circuits of pixels. The transistor layer TFTL may further include the gate lines, the data lines, the power lines, gate control lines, and fan-out lines connecting the data driver 200 and the data lines to each other. Each of the transistors may include a semiconductor region, a source electrode, a drain electrode, and a gate electrode. For example, when the gate driver is disposed on one side of the non-display area NDA of the display panel 100, the gate driver may include transistors.

The transistor layer TFTL may be disposed in the display area DA and the non-display area NDA. The transistors of each of the pixels, the gate lines, the data lines, and the power lines of the transistor layer TFTL may be disposed in the display area DA. The gate control lines and the fan-out lines of the transistor layer TFTL may be disposed in the non-display arca NDA.

The light emitting element layer EDL may be disposed on the transistor layer TFTL. The light emitting element layer EDL may include light emitting elements in which a pixel electrode, a light emitting layer, and a common electrode are sequentially stacked to emit light and a pixel defining film defining the pixels. The light emitting elements of the light emitting clement layer EDL may be disposed in the display arca DA.

For example, the light emitting layer may be an organic light emitting layer including an organic material. The light emitting layer may include a hole transporting layer, an organic light emitting layer, and an electron transporting layer. When the pixel electrode receives a predetermined voltage through the transistor of the transistor layer TFTL and the common electrode receives a cathode voltage, holes and electrons may move to the organic light emitting layer through the hole transporting layer and the electrode transporting layer, respectively, and may combine with each other in the organic light emitting layer to emit the light. For example, the pixel electrode may be an anode electrode and the common electrode may be a cathode electrode, but the present disclosure is not limited thereto.

As another example, a plurality of light emitting elements may include quantum dot light emitting diodes each including a quantum dot light emitting layer, inorganic light emitting diodes each including an inorganic semiconductor, or micro light emitting diodes.

The encapsulation layer TFEL may cover an upper surface and side surfaces of the light emitting element layer EDL and may protect the light emitting element layer EDL. The encapsulation layer TFEL may include at least one inorganic film and at least one organic film for encapsulating the light emitting clement layer EDL.

The touch sensing unit TSU may be disposed on the encapsulation layer TFEL. The touch sensing unit TSU may include a plurality of touch electrodes for sensing a user's touch in a capacitance manner and touch lines connecting the plurality of touch electrodes and a touch driver to each other. For example, the touch sensing unit TSU may sense the user's touch in a mutual capacitance manner or a self-capacitance manner. The plurality of touch electrodes of the touch sensing unit TSU may be disposed in a touch sensor area overlapping the display area DA. The touch lines of the touch sensing unit TSU may be disposed in a touch peripheral area overlapping the non-display area NDA.

As another example, the touch sensing unit TSU may be disposed on a separate substrate disposed on the display unit DU. In this case, the substrate supporting the touch sensing unit TSU may be a base member encapsulating the display unit DU.

The color filter layer CFL may be disposed on the touch sensing unit TSU. The color filter layer CFL may include a plurality of color filters corresponding to a plurality of emission areas, respectively. Each of the color filters may selectively transmit light of a specific wavelength therethrough and block or absorb light of other wavelengths. The color filter layer CFL may absorb some of light introduced from the outside of the display device 10 to reduce reflected light by external light. Accordingly, the color filter layer CFL may prevent distortion of colors due to external light reflection.

Since the color filter layer CFL is directly disposed on the touch sensing unit TSU, the display device 10 may not require a separate substrate for the color filter layer CFL. Accordingly, a thickness of the display device 10 may be relatively decreased.

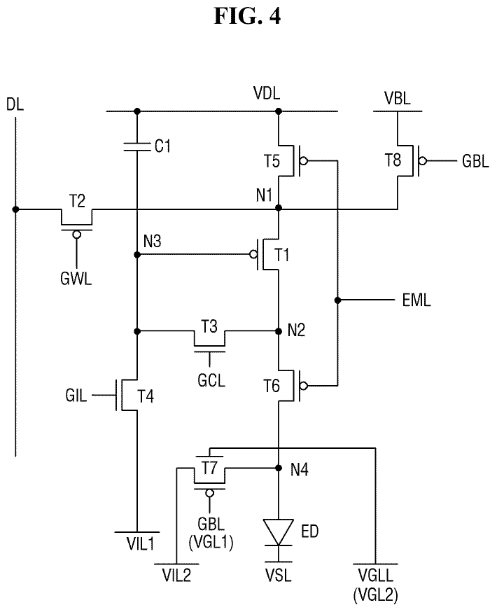

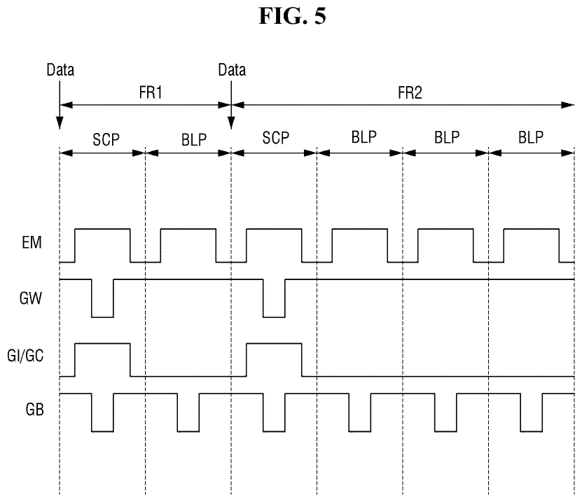

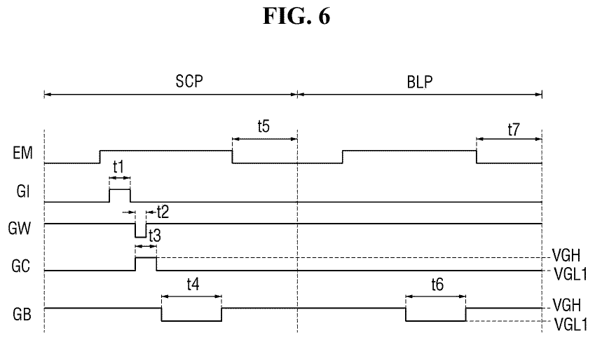

FIG. 4 is a circuit diagram illustrating a pixel of the display device according to an example embodiment, FIG. 5 is a timing diagram illustrating variable frequency driving of the display device according to an example embodiment, and FIG. 6 is a waveform diagram of signals supplied to the pixel illustrated in FIG. 4.

Referring to FIGS. 4 to 6, the pixel SP may be connected to a first gate line GWL, a second gate line GCL, a third gate line GIL, a fourth gate line GBL, an emission control line EML, a data line DL, a driving voltage line VDL, a first initialization voltage line VIL1, a second initialization voltage line VIL2, a bias voltage line VBL, a gate low voltage line VGLL, and a low potential line VSL.

The pixel SP may include a light emitting element ED and a pixel circuit driving the light emitting element ED. The pixel circuit may include first to eighth transistors T1, T2, T3, T4, T5, T6, T7, and T8 and a capacitor C1.

The first transistor T1 may control a driving current supplied to the light emitting element ED. The first transistor T1 may include a gate electrode, a first electrode, and a second electrode. The gate electrode of the first transistor T1 may be connected to a third node N3, the first electrode of the first transistor T1 may be connected to a first node N1, and the second electrode of the first transistor T1 may be connected to a second node N2. For example, the first electrode of the first transistor T1 may be a source electrode and the second electrode of the first transistor T1 may be a drain electrode, but the present disclosure is not limited thereto.

The first transistor T1 may control a source-drain current Isd (hereinafter, referred to as a “driving current”) according to a voltage of the gate electrode. The driving current Isd flowing through a channel of the first transistor T1 may be proportional to the square of a difference between a voltage Vsg between the source electrode and the gate electrode and a threshold voltage Vth of the first transistor T1 (Isd=k×(Vsg−Vth)²) Here, k refers to a proportional coefficient determined by a structure and physical properties of the first transistor T1, Vsg refers to a source-gate voltage of the first transistor T1, and Vth refers to the threshold voltage of the first transistor T1. The first transistor T1 may be referred to as a “driving transistor.”

The light emitting element ED may emit light by receiving the driving current Isd. A light emission amount or luminance of the light emitting element ED may be proportional to a magnitude of the driving current Isd. The light emitting element ED may include a first electrode, a second electrode, and a light emitting layer disposed between the first electrode and the second electrode. The first electrode of the light emitting element ED may be connected to a fourth node N4. The first electrode of the light emitting element ED may be electrically connected to a second electrode of the sixth transistor T6 and a first electrode of the seventh transistor T7 through the fourth node N4. The second electrode of the light emitting element ED may be electrically connected to the low potential line VSL. The second electrode of the light emitting element ED may receive a low potential voltage from the low potential line VSL. For example, the first electrode of the light emitting element ED may be an anode electrode or a pixel electrode, and the second electrode of the light emitting element ED may be a cathode electrode or a common electrode, but the present disclosure is not limited thereto.

The second transistor T2 may be turned on by a first gate signal GW of the first gate line GWL to electrically connect the data line DL and the first node N1, which is the first electrode of the first transistor T1, to each other. The second transistor T2 may be turned on based on the first gate signal GW to supply a data voltage to the first node N1. A gate electrode of the second transistor T2 may be connected to the first gate line GWL, a first electrode of the second transistor T2 may be connected to the data line DL, and a second electrode of the second transistor T2 may be connected to the first node N1. The second electrode of the second transistor T2 may be electrically connected to the first electrode of the first transistor T1, a second electrode of the fifth transistor T5, and a second electrode of the eighth transistor T8 through the first node N1. For example, the first electrode of the second transistor T2 may be a source electrode and the second electrode of the second transistor T2 may be a drain electrode, but the present disclosure is not limited thereto.

The third transistor T3 may be turned on by a second gate signal GC of the second gate line GCL to electrically connect the second node N2, which is the second electrode of the first transistor T1, and the third node N3, which is the gate electrode of the first transistor T1, to each other. A gate electrode of the third transistor T3 may be connected to the second gate line GCL, a first electrode of the third transistor T3 may be connected to the second node N2, and a second electrode of the third transistor T3 may be connected to the third node N3. The first electrode of the third transistor T3 may be electrically connected to the second electrode of the first transistor T1 and a first electrode of the sixth transistor T6 through the second node N2. The second electrode of the third transistor T3 may be electrically connected to the gate electrode of the first transistor T1, a first electrode of the fourth transistor T4, and a first capacitor electrode of the capacitor C1 through the third node N3. For example, the first electrode of the third transistor T3 may be a drain electrode and the second electrode of the third transistor T3 may be a source electrode, but the present disclosure is not limited thereto.

The fourth transistor T4 may be turned on by a third gate signal GI of the third gate line GIL to electrically connect the third node N3, which is the gate electrode of the first transistor T1, and the first initialization voltage line VIL1 to each other. The fourth transistor T4 may be turned on based on the third gate signal GI to initialize the gate electrode of the first transistor T1 to a first initialization voltage. A gate electrode of the fourth transistor T4 may be connected to the third gate line GIL, the first electrode of the fourth transistor T4 may be connected to the third node N3, and a second electrode of the fourth transistor T4 may be connected to the first initialization voltage line VIL1. The first electrode of the fourth transistor T4 may be electrically connected to the gate electrode of the first transistor T1, the second electrode of the third transistor T3, and the first capacitor electrode of the capacitor C1 through the third node N3. For example, the first electrode of the fourth transistor T4 may be a drain electrode and the second electrode of the fourth transistor T4 may be a source electrode, but the present disclosure is not limited thereto.

The fifth transistor T5 may be turned on by an emission signal of the emission control line EML to electrically connect the driving voltage line VDL and the first node N1, which is the first electrode of the first transistor T1, to each other. A gate electrode of the fifth transistor T5 may be connected to the emission control line EML, a first electrode of the fifth transistor T5 may be connected to the driving voltage line VDL, and the second electrode of the fifth transistor T5 may be connected to the first node N1. The second electrode of the fifth transistor T5 may be electrically connected to the first electrode of the first transistor T1, the second electrode of the second transistor T2, and the second electrode of the eighth transistor T8 through the first node N1. For example, the first electrode of the fifth transistor T5 may be a source electrode and the second electrode of the fifth transistor T5 may be a drain electrode, but the present disclosure is not limited thereto.

The sixth transistor T6 may be turned on by the emission signal of the emission control line EML to electrically connect the second node N2, which is the second electrode of the first transistor T1, and the fourth node N4, which is the first electrode of the light emitting element ED, to each other. A gate electrode of the sixth transistor T6 may be connected to the emission control line EML, the first electrode of the sixth transistor T6 may be connected to the second node N2, and the second electrode of the sixth transistor T6 may be connected to the fourth node N4. The first electrode of the sixth transistor T6 may be electrically connected to the second electrode of the first transistor T1 and the first electrode of the third transistor T3 through the second node N2. The second electrode of the sixth transistor T6 may be electrically connected to the first electrode of the light emitting element ED and the first electrode of the seventh transistor T7 through the fourth node N4. For example, the first electrode of the sixth transistor T6 may be a source electrode and the second electrode of the sixth transistor T6 may be a drain electrode, but the present disclosure is not limited thereto.

When the fifth transistor T5, the first transistor T1, and the sixth transistor T6 are all turned on, the driving current Isd may be supplied to the light emitting element ED.

The seventh transistor T7 may be turned on by a fourth gate signal GB of the fourth gate line GBL to electrically connect the second initialization voltage line VIL2 and the fourth node N4, which is the first electrode of the light emitting element ED, to each other. The seventh transistor T7 may be turned on based on the fourth gate signal GB to initialize the first electrode of the light emitting element ED to a second initialization voltage. Here, the second initialization voltage of the second initialization voltage line VIL2 may be different from the first initialization voltage of the first initialization voltage line VIL1. As another example, the second initialization voltage may be the same as the first initialization voltage. A gate electrode of the seventh transistor T7 may be connected to the fourth gate line GBL, the first electrode of the seventh transistor T7 may be connected to the fourth node N4, and a second electrode of the seventh transistor T7 may be connected to the second initialization voltage line VIL2. The first electrode of the seventh transistor T7 may be electrically connected to the first electrode of the light emitting element ED and the second electrode of the sixth transistor T6 through the fourth node N4. For example, the first electrode of the seventh transistor T7 may be a source electrode and the second electrode of the seventh transistor T7 may be a drain electrode, but the present disclosure is not limited thereto.

A bias electrode of the seventh transistor T7 may be connected to the gate low voltage line VGLL. A low level of the fourth gate signal GB may correspond to a first gate low voltage VGL1, and the bias electrode may receive a second gate low voltage VGL2 from the gate low voltage line VGLL. The first and second gate low voltages VGL1 and VGL2 may be negative voltages, and the first gate low voltage VGL1 may be greater than the second gate low voltage VGL2. An absolute value of the first gate low voltage VGL1 may be smaller than an absolute value of the second gate low voltage VGL2. The bias electrode of the seventh transistor T7 receives the second gate low voltage VGL2, and thus, may relatively decrease a threshold voltage of the seventh transistor T7 compared to a case where it does not receive the second gate low voltage VGL2. Since the threshold voltage of the seventh transistor T7 decreases, the first gate low voltage VGL1 received at the gate electrode of the seventh transistor T7 increases, such that the absolute value of the first gate low voltage VGL1 may decrease. Accordingly, the display device 10 may effectively reduce power consumption of the pixel circuit by supplying the second gate low voltage VGL2 to the bias electrode of the seventh transistor T7. Here, the seventh transistor T7 may be an “initialization transistor”.

The eighth transistor T8 may be turned on by the fourth gate signal GB of the fourth gate line GBL to electrically connect the bias voltage line VBL and the first node N1, which is the first electrode of the first transistor T1, to each other. A gate electrode of the eighth transistor T8 may be connected to the fourth gate line GBL, a first electrode of the eighth transistor T8 may be connected to the bias voltage line VBL, and the second electrode of the eighth transistor T8 may be connected to the first node N1. The second electrode of the eighth transistor T8 may be electrically connected to the first electrode of the first transistor T1, the second electrode of the second transistor T2, and the second electrode of the fifth transistor T5 through the first node N1. For example, the first electrode of the eighth transistor T8 may be a source electrode and the second electrode of the eighth transistor T8 may be a drain electrode, but the present disclosure is not limited thereto. Optionally, the eighth transistor T8 may be omitted.

Each of the first transistor T1, the second transistor T2, the fifth transistor T5, the sixth transistor T6, the seventh transistor T7, and the eighth transistor T8 may include a silicon-based semiconductor region. For example, each of the first transistor T1, the second transistor T2, the fifth transistor T5, the sixth transistor T6, the seventh transistor T7, and the eighth transistor T8 may include a semiconductor region made of low temperature polycrystalline silicon (“LTPS”). The semiconductor region made of low temperature polycrystalline silicon may have high electron mobility and excellent turn-on characteristics. Accordingly, the display device 10 may stably and efficiently drive the plurality of pixels SP by including the first transistor T1, the second transistor T2, the fifth transistor T5, the sixth transistor T6, the seventh transistor T7, and the eighth transistor T8 having the excellent turn-on characteristics.

Each of the first transistor T1, the second transistor T2, the fifth transistor T5, the sixth transistor T6, the seventh transistor T7, and the eighth transistor T8 may correspond to a P-type transistor. For example, each of the first transistor T1, the second transistor T2, the fifth transistor T5, the sixth transistor T6, the seventh transistor T7, and the eighth transistor T8 may output a current introduced into the first electrode to the second electrode based on the first gate low voltage VGL1 applied to the gate electrode.

Each of the third transistor T3 and the fourth transistor T4 may include an oxide-based semiconductor region. For example, each of the third transistor T3 and the fourth transistor T4 may have a coplanar structure in which the gate electrode is disposed above the oxide-based semiconductor region. The transistor having the coplanar structure may have excellent leakage current characteristics and may be driven at a low frequency to reduce power consumption. Accordingly, the display device 10 may prevent a leakage current from flowing inside the pixel and stably maintain a voltage inside the pixel, by including the third transistor T3 and the fourth transistor T4 that have the excellent leakage current characteristics.

Each of the third transistor T3 and fourth transistor T4 may correspond to an N-type transistor (e.g., NMOS). For example, each of the third transistor T3 and the fourth transistor T4 may output a current introduced into the first electrode to the second electrode based on a gate high voltage VGH applied to the gate electrode.

The capacitor C1 may be connected between the third node N3, which is the gate electrode of the first transistor T1, and the driving voltage line VDL. For example, the capacitor C1 may have the first capacitor electrode connected to the third node N3 and a second capacitor electrode connected to the driving voltage line VDL to maintain a potential difference between the driving voltage line VDL and the gate electrode of the first transistor T1.

Referring to FIGS. 5 and 6 in conjunction with FIG. 4, the display device 10 may be driven at a first driving frequency FRI and a second driving frequency FR2 lower than the first driving frequency FR1. The first driving frequency FRI may be an integer multiple of the second driving frequency FR2 but is not limited thereto. As the display device 10 is driven at a higher frequency, an input cycle of data Data may become shorter.

The display device 10 may be driven at a predetermined driving frequency, and one frame period may include one scanning section SCP and at least one blanking section BLP. For example, when the display device 10 is driven at the first driving frequency FRI, one frame period may include one scanning section SCP and one blanking section BLP. When the display device 10 is driven at the second driving frequency FR2, one frame period may include one scanning section SCP and three blanking sections BLP. The emission signal EM and the fourth gate signal GB may be supplied to the pixel circuit during the scanning section SCP and the blanking section BLP. The first to third gate signals GW, GC, and GI may be supplied to the pixel circuit during the scanning section SCP but may not be supplied to the pixel circuit during the blanking section BLP. The scanning section SCP may include first to fifth periods t1 to t5, and the blanking section BLP may include sixth and seventh periods t6 and t7.

The fourth transistor T4 may receive the third gate signal GI having a high level during the first period t1. The fourth transistor T4 may be turned on based on the third gate signal GI having the high level, and may initialize the third node N3, which is the gate electrode of the first transistor T1, to the first initialization voltage. Accordingly, the fourth transistor T4 may initialize the gate electrode of the first transistor T1 during the first period t1.

The second transistor T2 may receive the first gate signal GW having a low level during the second period t2. The second transistor T2 may be turned on based on the first gate signal GW having the low level, and may supply the data voltage to the first node N1, which is the source electrode of the first transistor T1.

The third transistor T3 may receive the second gate signal GC having a high level during the third period t3. The third transistor T3 may be turned on based on the second gate signal GC having the high level, and may electrically connect the second node N2 and the third node N3 to each other.

The seventh transistor T7 may receive the fourth gate signal GB having a low level during the fourth period t4. The seventh transistor T7 may be turned on based on the fourth gate signal GB having the low level, and may initialize the first electrode of the light emitting element ED to the second initialization voltage. Accordingly, the seventh transistor T7 may initialize the first electrode of the light emitting element ED during the fourth period t4.

The eighth transistor T8 may receive the fourth gate signal GB having the low level during the fourth period t4. The eighth transistor T8 may be turned on based on the fourth gate signal GB having the low level, and may supply the bias voltage to the first node N1, which is the source electrode of the first transistor T1. The eighth transistor T8 may set an operation point or an operation condition of the first transistor T1 during the fourth period t4. The eighth transistor T8 may prevent a change in characteristics of the first transistor T1 due to bias stress and improve hysteresis of the first transistor T1.

When the source electrode of the first transistor T1 receives the data voltage VDATA, the source-gate voltage Vsg of the first transistor T1 may correspond to a difference voltage (VDATA−VI1) between the data voltage VDATA and the first initialization voltage VI1, and may become greater than the threshold voltage Vth (VDATA−VI1>=Vth), such that the first transistor T1 may be turned on. Accordingly, at the moment when the second transistor T2 is turned on in the second period t2, the source-drain current Isd of the first transistor T1 may be determined according to the data voltage VDATA, the first initialization voltage VI1, and the threshold voltage Vth of the first transistor T1 (Isd=k×(VDATA−VI1−Vth)²). The first transistor T1 may supply the source-drain current Isd to the second node N2 until the source-gate voltage Vsg reaches the threshold voltage Vth of the first transistor T1. In addition, the third transistor T3 may be turned on during the third period t3 to supply a voltage of the second node N2 to the third node N3. In such a way, while the first transistor T1 is turned on, a voltage of the third node N3 and the source-drain current Isd of the first transistor T1 may be changed, and the voltage of the third node N3 may eventually converge to a difference voltage (VDATA−Vth) between the data voltage VDATA and the threshold voltage Vth of the first transistor T1.

The emission signal EM may have a gate low voltage during the fifth period t5. When the emission signal EM has a low level, the fifth and sixth transistors T5 and T6 may be turned on to supply the driving current to the light emitting element ED.

The fourth gate signal GB may have a gate low voltage during the sixth period t6 of the blanking section BLP. Accordingly, the seventh transistor T7 may initialize the fourth node N4, which is the first electrode of the light emitting element ED, to the second initialization voltage even in the blanking section BLP. The eighth transistor T8 may supply the bias voltage to the first node N1, which is the source electrode of the first transistor T1, even in the blanking section BLP, and may improve the hysteresis of the first transistor T1.

The emission signal EM may have a gate low voltage during the seventh period t7 of the blanking section BLP. Accordingly, when the emission signal EM has a low level, the fifth and sixth transistors T5 and T6 may be turned on to supply the driving current to the initialized first electrode of the light emitting element ED.

The low levels of the first and fourth gate signals GW and GB and the emission signal EM may correspond to the first gate low voltage VGL1, and the high levels of the second and third gate signals GC and GI may correspond to the gate high voltage VGH.

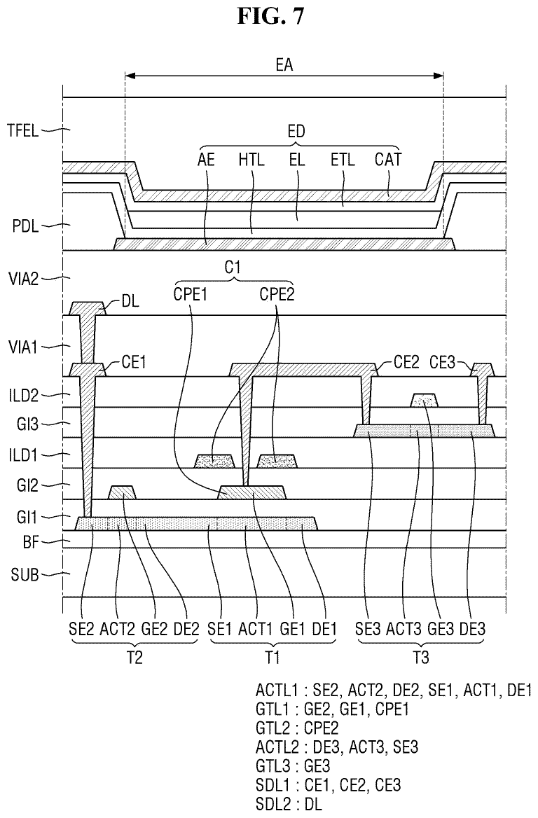

FIG. 7 is a cross-sectional view illustrating a portion of the pixel of FIG. 4.

Referring to FIG. 7, the display panel 100 may include a substrate SUB, a buffer layer BF, a first active layer ACTL1, a first gate insulating layer GI1, a first gate layer GTL1, a second gate insulating layer GI2, a second gate layer GTL2, a first interlayer-insulating layer ILD1, a second active layer ACT2, a third gate insulating layer GI3, a third gate layer GTL3, a second Interlayer-insulating layer ILD2, a first source metal layer SDL1, a first via-layer VIA1, a second source metal layer SDL2, a second via-layer VIA2, a pixel defining film PDL, a light emitting element ED, and an encapsulation layer TFEL.

The substrate SUB may be a base substrate or a base member. The substrate SUB may be a flexible substrate that may be bent, folded, and rolled. As an example, the substrate SUB may include a polymer resin such as polyimide (PI) but is not limited thereto. As another example, the substrate SUB may include a glass material or a metal material.

The buffer layer BF may be disposed on the substrate SUB. For example, the buffer layer BF may include an inorganic film capable of preventing permeation of air or moisture. For example, the buffer layer BF may include a plurality of inorganic films that are alternately stacked.

The first active layer ACTL1 may be disposed on the buffer layer BF. The first active layer ACTL1 may include a silicon-based material. For example, the first active layer ACTL1 may be made of low temperature polycrystalline silicon (“LTPS”). The first active layer ACTL1 may include a semiconductor region ACT1, a first electrode SE1, and a second electrode DE1 of the first transistor T1, and a semiconductor region ACT2, a first electrode SE2, and a second electrode DE2 of the second transistor T2.

The first gate insulating layer GI1 may be disposed on the first active layer ACTL1. The first gate insulating layer GI1 may insulate the first active layer ACTL1 and the first gate layer GTL1 from each other.

The first gate layer GTL1 may be disposed on the first gate insulating layer GI1. The first gate layer GTL1 may include a gate electrode GE1 of the first transistor T1, a gate electrode GE2 of the second transistor T2, and a first capacitor electrode CPE1. The gate electrode GE1 of the first transistor T1 may be a portion of the first capacitor electrode CPE1, and the gate electrode GE2 of the second transistor T2 may be a portion of the first gate line GWL.

The second gate insulating layer GI2 may be disposed on the first gate layer GTL1. The second gate insulating layer GI2 may insulate the first gate layer GTL1 and the second gate layer GTL2 from each other.

The second gate layer GTL2 may be disposed on the second gate insulating layer GI2. The second gate layer GTL2 may include a second capacitor electrode CPE2. The second capacitor electrode CPE2 may overlap the first capacitor electrode CPE1 in a plan view.

The first interlayer-insulating layer ILD1 may be disposed on the second gate layer GTL2. The first interlayer-insulating layer ILD1 may insulate the second gate layer GTL2 and the second active layer ACTL2 from each other.

The second active layer ACTL2 may be disposed on the first interlayer-insulating layer ILD1. The second active layer ACTL2 may include an oxide-based material. The second active layer ACTL2 may include a semiconductor region ACT3, a first electrode DE3, and a second electrode SE3 of the third transistor T3.

The third gate insulating layer GI3 may be disposed on the second active layer ACTL2. The third gate insulating layer GI3 may insulate the second active layer ACTL2 and the third gate layer GTL3 from each other.

The third gate layer GTL3 may be disposed on the third gate insulating layer GI3. The third gate layer GTL3 may include a gate electrode GE3 of the third transistor T3. The gate electrode GE3 of the third transistor T3 may be a portion of the second gate line GCL.

The second interlayer-insulating layer ILD2 may be disposed on the third gate layer GTL3. The second interlayer-insulating layer ILD2 may insulate the third gate layer GTL3 and the first source metal layer SDL1 from each other.

The first source metal layer SDL1 may be disposed on the second interlayer-insulating layer ILD2. The first source metal layer SDL1 may include first to third connection electrodes CE1, CE2, and CE3. The first connection electrode CE1 may electrically connect the data line DL and the first electrode SE2 of the second transistor T2 to each other. The second connection electrode CE2 may electrically connect the first capacitor electrode CPE1 and the second electrode SE3 of the third transistor T3 to each other. The third connection electrode CE3 may electrically connect the first electrode DE3 of the third transistor T3 and the second electrode DE1 of the first transistor T1 to each other.

The first via-layer VIA1 may be disposed on the first source metal layer SDL1. The first via-layer VIA1 may insulate the first source metal layer SDL1 and the second source metal layer SDL2 from each other. An upper surface of the first via-layer VIA1 may be flat. The first via-layer VIA1 may include an organic insulating material such as polyimide (PI). The second source metal layer SDL2 may be disposed on the first via-layer VIA1.

The second source metal layer SDL2 may include the data line DL. The second via-layer VIA2 may be disposed on the second source metal layer SDL2. The second via-layer VIA2 may insulate the second source metal layer SDL2 and a pixel electrode AE from each other. An upper surface of the second via-layer VIA2 may be flat. The second via-layer VIA2 may include an organic insulating material such as polyimide (PI).

The pixel defining film PDL may be disposed on the second via-layer VIA2. The pixel defining film PDL may define a plurality of emission areas EA. The pixel defining film PDL may include an organic insulating material such as polyimide (PI).

The light emitting element ED may include the pixel electrode AE, a hole transporting layer HTL, a light emitting layer EL, an electron transporting layer ETL, and a common electrode CAT. The pixel electrode AE may be disposed on the second via-layer VIA2. The pixel electrode AE may overlap one of the plurality of emission areas EA defined by the pixel defining film PDL. The pixel electrode AE may receive the driving current from the pixel circuit of the pixel SP.

The hole transporting layer HTL may be disposed on the pixel electrode AE in the emission area EA and disposed on the pixel defining film PDL in a non-emission area. The hole transporting layer HTL is not divided for each pixel SP, and may be implemented as a common layer for all pixels SP.

The light emitting layer EL may be disposed on the hole transporting layer HTL in the emission area EA. For example, the light emitting layer EL may be an organic light emitting layer made of an organic material but is not limited thereto.

The electron transporting layer ETL may be disposed on the light emitting layer EL in the emitting area EA and disposed on the hole transporting layer HTL in the non-emission area. The electron transporting layer ETL is not divided for each pixel SP, and may be implemented as a common layer for all pixels SP.

The common electrode CAT may be disposed on the electron transporting layer ETL. For example, the common electrode CAT is not divided for each of the plurality of pixels SP, and may be implemented in the form of an electrode common to all pixels SP. The common electrode CAT may be a transparent electrode and may transmit light therethrough. The common electrode CAT may be electrically connected to the low potential line VSL, and may receive a low potential voltage, a common voltage, or a cathode voltage.

In a case where the light emitting layer EL is the organic light emitting layer, when the pixel circuit of the pixel SP applies a predetermined voltage to the pixel electrode AE and the common electrode CAT receives the common voltage or the cathode voltage, holes and electrons may move to the light emitting layer EL through the hole transporting layer HTL and the electron transporting layer ETL, respectively, and may be combined with each other in the light emitting layer EL to emit light.

The encapsulation layer TFEL may be disposed on the common electrodes CAT to cover a plurality of light emitting elements ED. The encapsulation layer TFEL may include at least one inorganic film to prevent oxygen or moisture from permeating into the plurality of light emitting elements ED. The encapsulation layer TFEL may include at least one organic film to protect the plurality of light emitting elements ED from foreign substances such as dust.

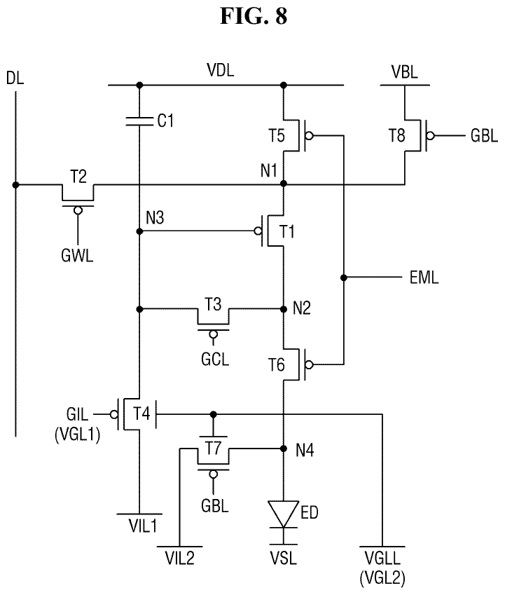

FIG. 8 is a circuit diagram illustrating a pixel of a display device according to another example embodiment. A pixel in FIG. 8 is different from the pixel of FIG. 4 in third and fourth transistors T3 and T4, and the same configurations as the configurations described above will be briefly described or a description thereof will be omitted.

The pixel SP may be connected to a first gate line GWL, a second gate line GCL, a third gate line GIL, a fourth gate line GBL, an emission control line EML, a data line DL, a driving voltage line VDL, a first initialization voltage line VIL1, a second initialization voltage line VIL2, a bias voltage line VBL, a gate low voltage line VGLL, and a low potential line VSL.

The pixel SP may include a light emitting element ED and a pixel circuit driving the light emitting element ED. The pixel circuit may include first to eighth transistors T1, T2, T3, T4, T5, T6, T7, and T8 and a capacitor C1.

The first transistor T1 may control a driving current supplied to the light emitting element ED. A gate electrode of the first transistor T1 may be connected to a third node N3, a first electrode of the first transistor T1 may be connected to a first node N1, and a second electrode of the first transistor T1 may be connected to a second node N2.

The light emitting element ED may emit light by receiving the driving current Isd. A first electrode of the light emitting element ED may be connected to a fourth node N4. A second electrode of the light emitting element ED may be electrically connected to the low potential line VSL. The second electrode of the light emitting element ED may receive a low potential voltage from the low potential line VSL.

The second transistor T2 may be turned on based on a first gate signal GW to supply a data voltage to the first node N1. A gate electrode of the second transistor T2 may be connected to the first gate line GWL, a first electrode of the second transistor T2 may be connected to the data line DL, and a second electrode of the second transistor T2 may be connected to the first node N1.

The third transistor T3 may be turned on by a second gate signal GC having a low level to electrically connect the second node N2, which is the second electrode of the first transistor T1, and the third node N3, which is the gate electrode of the first transistor T1, to each other. A gate electrode of the third transistor T3 may be connected to the second gate line GCL, a first electrode of the third transistor T3 may be connected to the second node N2, and a second electrode of the third transistor T3 may be connected to the third node N3. The first electrode of the third transistor T3 may be electrically connected to the second electrode of the first transistor T1 and a first electrode of the sixth transistor T6 through the second node N2. The second electrode of the third transistor T3 may be electrically connected to the gate electrode of the first transistor T1, a first electrode of the fourth transistor T4, and a first capacitor electrode of the capacitor C1 through the third node N3. For example, the first electrode of the third transistor T3 may be a source electrode and the second electrode of the third transistor T3 may be a drain electrode, but the present disclosure is not limited thereto.

The fourth transistor T4 may be turned on by a third gate signal GI having a low level to electrically connect the third node N3, which is the gate electrode of the first transistor T1, and the first initialization voltage line VIL1 to each other. The fourth transistor T4 may be turned on based on the third gate signal GI to initialize the gate electrode of the first transistor T1 to a first initialization voltage. A gate electrode of the fourth transistor T4 may be connected to the third gate line GIL, the first electrode of the fourth transistor T4 may be connected to the third node N3, and a second electrode of the fourth transistor T4 may be connected to the first initialization voltage line VIL1. The first electrode of the fourth transistor T4 may be electrically connected to the gate electrode of the first transistor T1, the second electrode of the third transistor T3, and the first capacitor electrode of the capacitor C1 through the third node N3. For example, the first electrode of the fourth transistor T4 may be a source electrode and the second electrode of the fourth transistor T4 may be a drain electrode, but the present disclosure is not limited thereto.

A bias electrode of the fourth transistor T4 may be connected to the gate low voltage line VGLL. The low level of the third gate signal GI may correspond to a first gate low voltage VGL1, and the bias electrode may receive a second gate low voltage VGL2 from the gate low voltage line VGLL. The first and second gate low voltages VGL1 and VGL2 may be negative voltages, and the first gate low voltage VGL1 may be greater than the second gate low voltage VGL2. An absolute value of the first gate low voltage VGL1 may be smaller than an absolute value of the second gate low voltage VGL2. The bias electrode of the fourth transistor T4 receives the second gate low voltage VGL2, and thus, may relatively decrease a threshold voltage of the fourth transistor T4 compared to a case where it does not receive the second gate low voltage VGL2. Since the threshold voltage of the fourth transistor T4 decreases, the first gate low voltage VGL1 received at the gate electrode of the fourth transistor T4 increases, such that the absolute value of the first gate low voltage VGL1 may decrease. Accordingly, the display device 10 may effectively reduce power consumption of the pixel circuit by supplying the second gate low voltage VGL2 to the bias electrode of the fourth transistor T4. Here, the fourth transistor T4 may be an “initialization transistor”.

The fifth transistor T5 may be turned on by an emission signal of the emission control line EML to electrically connect the driving voltage line VDL and the first node N1, which is the first electrode of the first transistor T1, to each other. A gate electrode of the fifth transistor T5 may be connected to the emission control line EML, a first electrode of the fifth transistor T5 may be connected to the driving voltage line VDL, and a second electrode of the fifth transistor T5 may be connected to the first node N1.

The sixth transistor T6 may be turned on by the emission signal of the emission control line EML to electrically connect the second node N2, which is the second electrode of the first transistor T1, and the fourth node N4, which is the first electrode of the light emitting element ED, to each other. A gate electrode of the sixth transistor T6 may be connected to the emission control line EML, the first electrode of the sixth transistor T6 may be connected to the second node N2, and a second electrode of the sixth transistor T6 may be connected to the fourth node N4.

The seventh transistor T7 may be turned on based on a fourth gate signal GB to initialize the first electrode of the light emitting element ED to a second initialization voltage. A gate electrode of the seventh transistor T7 may be connected to the fourth gate line GBL, a first electrode of the seventh transistor T7 may be connected to the fourth node N4, and a second electrode of the seventh transistor T7 may be connected to the second initialization voltage line VIL2.

A bias electrode of the seventh transistor T7 may be connected to the gate low voltage line VGLL. A low level of the fourth gate signal GB may correspond to the first gate low voltage VGL1, and the bias electrode may receive the second gate low voltage VGL2 from the gate low voltage line VGLL. The first and second gate low voltages VGL1 and VGL2 may be negative voltages, and the first gate low voltage VGL1 may be greater than the second gate low voltage VGL2. An absolute value of the first gate low voltage VGL1 may be smaller than an absolute value of the second gate low voltage VGL2. The bias electrode of the seventh transistor T7 receives the second gate low voltage VGL2, and thus, may relatively decrease a threshold voltage of the seventh transistor T7 compared to a case where it does not receive the second gate low voltage VGL2. Since the threshold voltage of the seventh transistor T7 decreases, the first gate low voltage VGL1 received at the gate electrode of the seventh transistor T7 increases, such that the absolute value of the first gate low voltage VGL1 may decrease. Accordingly, the display device 10 may effectively reduce power consumption of the pixel circuit by supplying the second gate low voltage VGL2 to the bias electrode of the seventh transistor T7.

The eighth transistor T8 may be turned on by the fourth gate signal GB of the fourth gate line GBL to electrically connect the bias voltage line VBL and the first node N1, which is the first electrode of the first transistor T1, to each other. A gate electrode of the eighth transistor T8 may be connected to the fourth gate line GBL, a first electrode of the eighth transistor T8 may be connected to the bias voltage line VBL, and a second electrode of the eighth transistor T8 may be connected to the first node N1.

Each of the first to eighth transistors T1, T2, T3, T4, T5, T6, T7, and T8 may include a silicon-based semiconductor region. For example, each of the first to eighth transistors T1, T2, T3, T4, T5, T6, T7, and T8 may include a semiconductor region made of low temperature polycrystalline silicon (LTPS). The semiconductor region made of low temperature polycrystalline silicon may have high electron mobility and excellent turn-on characteristics. Accordingly, the display device 10 may stably and efficiently drive the plurality of pixels SP by including the first to eighth transistors T1, T2, T3, T4, T5, T6, T7, and T8 having the excellent turn-on characteristics.

Each of the first to eighth transistors T1, T2, T3, T4, T5, T6, T7, and T8 may correspond to a P-type transistor. For example, each of the first to eighth transistors T1, T2, T3, T4, T5, T6, T7, and T8 may output a current introduced into the first electrode to the second electrode based on the first gate low voltage VGL1 applied to the gate electrode.

The capacitor C1 may be connected between the third node N3, which is the gate electrode of the first transistor T1, and the driving voltage line VDL. For example, the capacitor C1 may have the first capacitor electrode connected to the third node N3 and a second capacitor electrode connected to the driving voltage line VDL to maintain a potential difference between the driving voltage line VDL and the gate electrode of the first transistor T1.

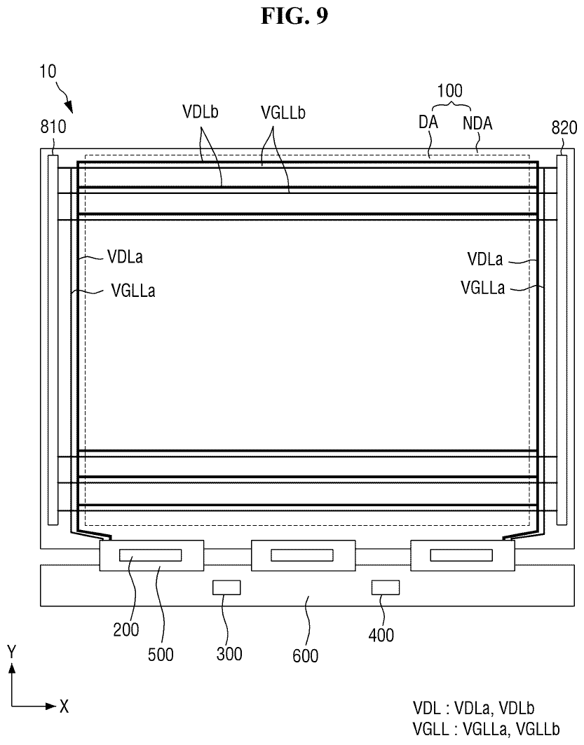

FIG. 9 is a diagram (plan view) illustrating an example of a driving voltage line and a gate low voltage line in the display device according to an example embodiment.

Referring to FIG. 9, the driving voltage line VDL may include a vertical portion VDLa and a horizontal portion VDLb. The vertical portion VDLa of the driving voltage line VDL may be connected to the data circuit board 500 on the lower side of the non-display arca NDA and may extend in the Y-axis direction on the left side and the right side of the non-display area NDA. The vertical portion VDLa of the driving voltage line VDL may be disposed between the display area DA and the gate driver 810 on the left side of the non-display area NDA and may be disposed between the display area DA and the emission control driver 820 on the right side of the non-display area NDA.

The horizontal portion VDLb of the driving voltage line VDL may be disposed between the vertical portions VDLa. A plurality of horizontal portions VDLb may be spaced apart from each other in the Y-axis direction. The horizontal portion VDLb of the driving voltage line VDL may receive the driving voltage from the vertical portion VDLa and supply the driving voltage to the pixel circuit of the pixel SP.

The gate low voltage line VGLL may include a vertical portion VGLLa and a horizontal portion VGLLb. The vertical portion VGLLa of the gate low voltage line VGLL may be connected to the data circuit board 500 on the lower side of the non-display area NDA, and may extend in the Y-axis direction on the left side and the right side of the non-display area NDA. The vertical portion VGLLa of the gate low voltage line VGLL may be disposed between the display area DA and the gate driver 810 on the left side of the non-display area NDA, and may be disposed between the display area DA and the emission control driver 820 on the right side of the non-display area NDA.

The horizontal portion VGLLb of the gate low voltage line VGLL may extend from the gate driver 810 to the emission control driver 820 in the X-axis direction. A plurality of horizontal portions VGLLb may be spaced apart from each other in the Y-axis direction. The horizontal portion VGLLb of the gate low voltage line VGLL may receive the second gate low voltage VGL2 from the vertical portion VGLLa and supply the second gate low voltage VGL2 to the pixel circuit of the pixel SP, the gate driver 810, and the emission control driver 820. Accordingly, the display device 10 may effectively reduce power consumption of the pixel circuit without adding a separate source voltage by using the second gate low voltage VGL2 supplied to the gate driver 810 and the emission control driver 820 in the pixel circuit of the pixel SP.

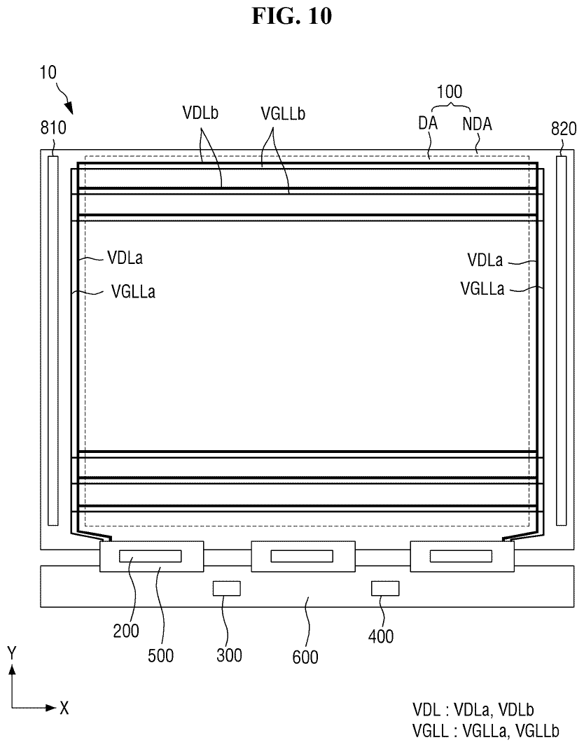

FIG. 10 is a diagram (plan view) illustrating another example of a driving voltage line and a gate low voltage line in the display device according to an example embodiment. A display device of FIG. 10 is different from the display device of FIG. 9 in a configuration of a gate low voltage line, and the same configurations as the configurations described above will be briefly described or a description thereof will be omitted.

Referring to FIG. 10, the gate low voltage line VGLL may include a vertical portion VGLLa and a horizontal portion VGLLb. The vertical portion VGLLa of the gate low voltage line VGLL may be connected to the data circuit board 500 on the lower side of the non-display area NDA, and may extend in the Y-axis direction on the left side and the right side of the non-display area NDA. The vertical portion VGLLa of the gate low voltage line VGLL may be disposed between the display area DA and the gate driver 810 on the left side of the non-display area NDA, and may be disposed between the display area DA and the emission control driver 820 on the right side of the non-display area NDA.

The horizontal portion VGLLb of the gate low voltage line VGLL may be disposed between the vertical portions VGLLa. A plurality of horizontal portions VGLLb may be spaced apart from each other in the Y-axis direction. The horizontal portion VGLLb of the gate low voltage line VGLL may receive the second gate low voltage VGL2 from the vertical portion VGLLa and supply the second gate low voltage VGL2 to the pixel circuit of the pixel SP. In this case, a plurality of stages of the gate driver 810 may not receive the second gate low voltage VGL2. Accordingly, the display device 10 may effectively reduce power consumption of the pixel circuit by supplying the second gate low voltage VGL2 to the pixel circuit of the pixel SP.

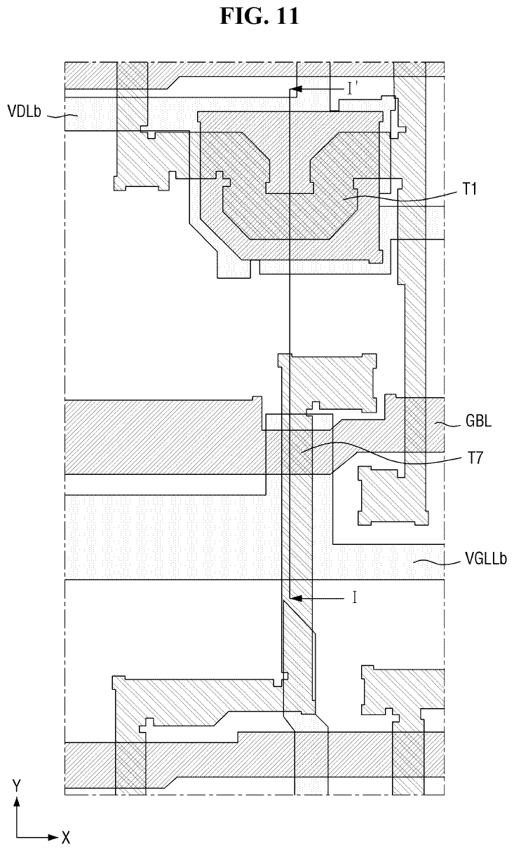

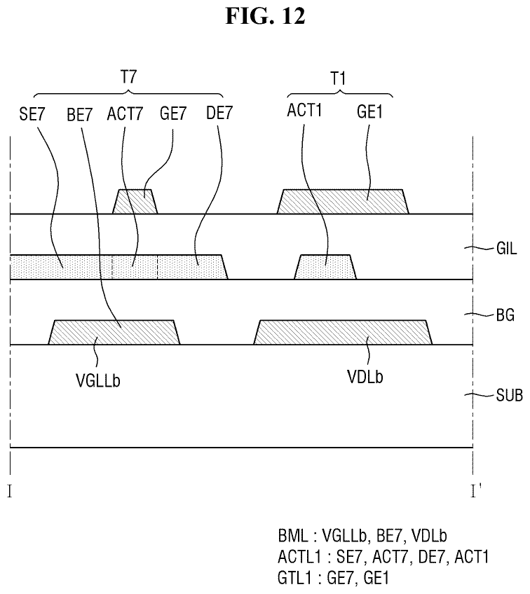

FIG. 11 is a layout diagram illustrating a portion of the pixel in the display device according to an example embodiment, and FIG. 12 is a cross-sectional view taken along line I-I′ of FIG. 11.

Referring to FIGS. 11 and 12, the horizontal portion VDLb of the driving voltage line VDL may be disposed at a bottom metal layer BML and extend in the X-axis direction. The bottom metal layer BML may be disposed on the substrate SUB. The horizontal portion VDLb of the driving voltage line VDL may receive the driving voltage from the vertical portion VDLa and supply the driving voltage to the pixel circuit of the pixel SP. The horizontal portion VDLb of the driving voltage line VDL may overlap the semiconductor region ACT1 and the gate electrode GE1 of the first transistor T1 in a plan view.

The horizontal portion VGLLb of the gate low voltage line VGLL may be disposed at the bottom metal layer BML and extend in the X-axis direction. The horizontal portion VGLLb of the gate low voltage line VGLL may receive the second gate low voltage VGL2 from the vertical portion VGLLa and supply the second gate low voltage VGL2 to a bias electrode BE7 of the seventh transistor T7. The bias electrode BE7 of the seventh transistor T7 may be a portion of the horizontal portion VGLLb of the gate low voltage line VGLL. The bias electrode BE7 of the seventh transistor T7 may overlap a semiconductor region ACT7 and a gate electrode GE7 of the seventh transistor T7.

The semiconductor region ACT7, a first electrode SE7, and a second electrode DE7 of the seventh transistor T7 may be disposed at the first active layer ACTL1, and the gate electrode GE7 of the seventh transistor T7 may be disposed at the first gate layer GTL1. The gate electrode GE7 of the seventh transistor T7 may be a portion of the fourth gate line GBL. The fourth gate line GBL may be disposed at the first gate layer GTL1 and extend in the X-axis direction.

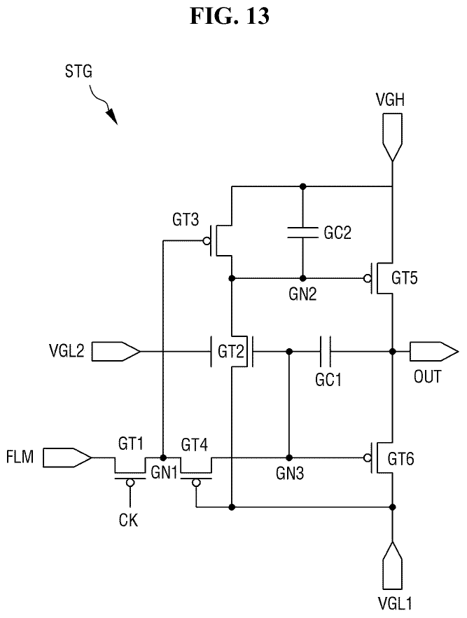

FIG. 13 is a circuit diagram illustrating an example of a stage of a gate driver in the display device according to an example embodiment.

Referring to FIG. 13, the gate driver 810 may include a plurality of stages STG. The stage STG may receive a gate input signal and output a gate signal. For example, the stage STG may receive at least some of a clock signal CK, a clock bar signal, a carry clock signal, a start signal FLM, an input signal, an initialization signal, a gate high voltage VGH, and first and second gate low voltages VGL1 and VGL2 and generate a gate signal, but the number and types of gate input signals are not limited thereto. Each of the stages STG may supply the gate signal to each of the gate lines GL.

The stage STG may include first to sixth gate transistors GT1, GT2, GT3, GT4, GT5, and GT6 and first and second gate capacitors GC1 and GC2.

The first gate transistor GTI may supply the start signal FLM to a first stage node GNI based on the clock signal CK. A gate electrode of the first gate transistor GTI may receive the clock signal CK, a first electrode of the first gate transistor GTI may receive the start signal FLM, and a second electrode of the first gate transistor GT1 may be connected to the first stage node GN1.

The second gate transistor GT2 may supply the first gate low voltage VGL1 to a second stage node GN2 based on a voltage of a third stage node GN3. A gate electrode of the second gate transistor GT2 may be connected to the third stage node GN3, a first electrode of the second gate transistor GT2 may be connected to the second stage node GN2, and a second electrode of the second gate transistor GT2 may receive the first gate low voltage VGL1. A bias electrode of the second gate transistor GT2 may be connected to the gate low voltage line VGLL to receive the second gate low voltage VGL2. The second gate low voltage VGL2 applied to the stage STG may also be applied to the pixel circuits of FIGS. 4 and 8. The first and second gate low voltages VGL1 and VGL2 may be negative voltages, and the first gate low voltage VGL1 may be greater than the second gate low voltage VGL2. An absolute value of the first gate low voltage VGL1 may be smaller than an absolute value of the second gate low voltage VGL2.

The third gate transistor GT3 may supply the gate high voltage VGH to the second stage node GN2 based on a voltage of the first stage node GN1. A gate electrode of the third gate transistor GT3 may be connected to the first stage node GN1, a first electrode of the third gate transistor GT3 may receive the gate high voltage VGH, and a second electrode of the third gate transistor GT3 may be connected to the second stage node GN2.

The fourth gate transistor GT4 may electrically connect the first stage node GN1 and the third stage node GN3 to each other based on the first gate low voltage VGL1. A gate electrode of the fourth gate transistor GT4 may receive the first gate low voltage VGL1, a first electrode of the fourth gate transistor GT4 may be connected to the first stage node GN1, and a second electrode of the fourth gate transistor GT4 may be connected to the third stage node GN3.

The fifth gate transistor GT5 may output the gate high voltage VGH as the gate signal based on a voltage of the second stage node GN2. A gate electrode of the fifth gate transistor GT5 may be connected to the second stage node GN2, a first electrode of the fifth gate transistor GT5 may receive the gate high voltage VGH, and a second electrode of the fifth gate transistor GT5 may be connected to an output node OUT. The fifth gate transistor GT5 may be a pull-up transistor of the stage STG but is not limited thereto.

The sixth gate transistor GT6 may output the first gate low voltage VGL1 as the gate signal based on the voltage of the third stage node GN3. A gate electrode of the sixth gate transistor GT6 may be connected to the third stage node GN3, a first electrode of the sixth gate transistor GT6 may be connected to the output node, and a second electrode of the sixth gate transistor GT6 may receive the first gate low voltage VGL1. The sixth gate transistor GT6 may be a pull-down transistor of the stage STG but is not limited thereto.

Each of the first and third to sixth gate transistors GT1, GT3, GT4, GT5, and GT6 may include a silicon-based active layer. For example, each of the first and third to sixth gate transistors GT1, GT3, GT4, GT5, and GT6 may include an active layer made of low temperature polycrystalline silicon (LTPS). The active layer made of low temperature polycrystalline silicon may have high electron mobility and excellent turn-on characteristics. Accordingly, the stage STG may be driven stably and efficiently by including the transistors having the excellent turn-on characteristics.

Each of the first and third to sixth gate transistors GT1, GT3, GT4, GT5, and GT6 may be a P-type transistor. For example, each of the first and third to sixth gate transistors GT1, GT3, GT4, GT5, and GT6 may output a current introduced into the first electrode to the second electrode based on a gate low voltage applied to the gate electrode.

The second gate transistor GT2 may include an oxide-based semiconductor region. For example, the second gate transistor GT2 may have a coplanar structure in which the gate electrode is disposed above the oxide-based semiconductor region. The transistor having the coplanar structure may have excellent leakage current characteristics and may be driven at a low frequency to reduce power consumption. Accordingly, the stage STG may prevent a leakage current from flowing and stably maintain a voltage inside the stage STG, by including the second gate transistor GT2 having the excellent leakage current characteristics.

The second gate transistor GT2 may correspond to an N-type transistor. For example, the second gate transistor GT2 may output a current flowing into the first electrode to the second electrode based on a voltage of the gate electrode.

The first gate capacitor GC1 may be connected between the third stage node GN3 and the output node OUT. Accordingly, the first gate capacitor GC1 may maintain a potential difference between the third stage node GN3 and the output node OUT.

The second gate capacitor GC2 may be connected between the gate high voltage VGH and the second stage node GN2. Accordingly, the second gate capacitor GC2 may maintain a potential difference between the gate high voltage VGH and the second stage node GN2.

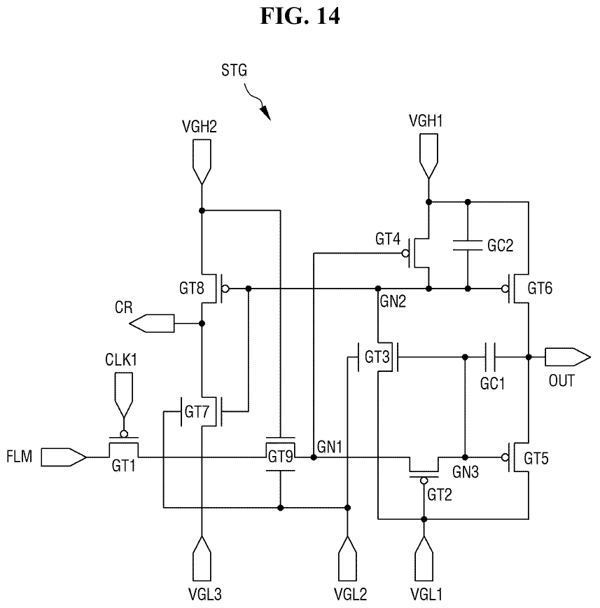

FIG. 14 is a circuit diagram illustrating another example of a stage of a gate driver in a display device according to another example embodiment.

Referring to FIG. 14, the gate driver 810 may include a plurality of stages STG. The stage STG may receive a gate input signal and output a gate signal. For example, the stage STG may receive at least some of a first clock signal CLK1, a clock bar signal, a carry clock signal, a start signal FLM, an input signal, an initialization signal, first and second gate high voltages VGH1 and VGH2, and first to third gate low voltages VGL1, VGL2, and VGL3 and generate a gate signal, but the number and types of gate input signals are not limited thereto. Each of the stages STG may supply the gate signal to each of the gate lines GL.

The stage STG may include first to ninth gate transistors GT1, GT2, GT3, GT4, GT5, GT6, GT7, GT8, and GT9 and first and second gate capacitors GC1 and GC2.

The first gate transistor GT1 may supply the start signal FLM to a first electrode of the ninth gate transistor GT9 based on the first clock signal CLK1. A gate electrode of the first gate transistor GT1 may receive the first clock signal CLK1, a first electrode of the first gate transistor GT1 may receive the start signal FLM, and a second electrode of the first gate transistor GTI may be connected to the first electrode of the ninth gate transistor GT9.

The second gate transistor GT2 may electrically connect a first stage node GNI and a third stage node GN3 to each other based on the first gate low voltage VGL1. A gate electrode of the second gate transistor GT2 may receive the first gate low voltage VGL1, a first electrode of the second gate transistor GT2 may be connected to the first stage node GN1, and a second electrode of the second gate transistor GT2 may be connected to the third stage node GN3.

The third gate transistor GT3 may supply the first gate low voltage VGL1 to a second stage node GN2 based on a voltage of the third stage node GN3. A gate electrode of the third gate transistor GT3 may be connected to the third stage node GN3, a first electrode of the third gate transistor GT3 may be connected to the second stage node GN2, and a second electrode of the third gate transistor GT3 may receive the first gate low voltage VGL1. A bias electrode of the third gate transistor GT3 may be connected to the gate low voltage line VGLL to receive the second gate low voltage VGL2. The second gate low voltage VGL2 applied to the stage STG may also be applied to the pixel circuits of FIGS. 4 and 8. The first and second gate low voltages VGL1 and VGL2 may be negative voltages, and the first gate low voltage VGL1 may be greater than the second gate low voltage VGL2. An absolute value of the first gate low voltage VGL1 may be smaller than an absolute value of the second gate low voltage VGL2.

The fourth gate transistor GT4 may supply the first gate high voltage VGH1 to the second stage node GN2 based on a voltage of the first stage node GN1. A gate electrode of the fourth gate transistor GT4 may be connected to the first stage node GN1, a first electrode of the fourth gate transistor GT4 may receive the first gate high voltage VGH1, and a second electrode of the fourth gate transistor GT4 may be connected to the second stage node GN2.

The fifth gate transistor GT5 may output the first gate low voltage VGL1 as the gate signal based on the voltage of the third stage node GN3. A gate electrode of the fifth gate transistor GT5 may be connected to the third stage node GN3, a first electrode of the fifth gate transistor GT5 may be connected to an output node, and a second electrode of the fifth gate transistor GT5 may receive the first gate low voltage VGL1. The fifth gate transistor GT5 may be a pull-down transistor of the stage STG but is not limited thereto.

The sixth gate transistor GT6 may output the first gate high voltage VGH1 as the gate signal based on a voltage of the second stage node GN2. A gate electrode of the sixth gate transistor GT6 may be connected to the second stage node GN2, a first electrode of the sixth gate transistor GT6 may receive the first gate high voltage VGH1, and a second electrode of the sixth gate transistor GT6 may be connected to the output node OUT. The sixth gate transistor GT6 may be a pull-up transistor of the stage STG but is not limited thereto.

The seventh gate transistor GT7 may output the third gate low voltage VGL3 as a carry signal based on the voltage of the second stage node GN2. A gate electrode of the seventh gate transistor GT7 may be connected to the second stage node GN2, a first electrode of the seventh gate transistor GT7 may be connected to a carry output node CR, and a second electrode of the seventh gate transistor GT7 may receive the third gate low voltage VGL3. The first and third gate low voltages VGL1 and VGL3 may be negative voltages, and the third gate low voltage VGL3 may be greater than the first gate low voltage VGL1. An absolute value of the third gate low voltage VGL3 may be smaller than the absolute value of the first gate low voltage VGL1. A bias electrode of the seventh gate transistor GT7 may be connected to the gate low voltage line VGLL to receive the second gate low voltage VGL2.

The eighth gate transistor GT8 may output the second gate high voltage VGH2 as the carry signal based on the voltage of the second stage node GN2. A gate electrode of the eighth gate transistor GT8 may be connected to the second stage node GN2, a first electrode of the eighth gate transistor GT8 may receive the second gate high voltage VGH2, and a second electrode of the eighth gate transistor GT8 may be connected to the carry output node CR. The first and second gate high voltages VGH1 and VGH2 may be positive voltages, and the first gate high voltage VGH1 may be greater than the second gate high voltage VGH2.

The ninth gate transistor GT9 may electrically connect the second electrode of the first gate transistor GT1 and the first stage node GNI to each other based on the second gate high voltage VGH2. A gate electrode of the ninth gate transistor GT9 may receive the second gate high voltage VGH2, the first electrode of the ninth gate transistor GT9 may be connected to the second electrode of the first gate transistor GT1, and a second electrode of the ninth gate transistor GT9 may be connected to the first stage node GN1. A bias electrode of the ninth gate transistor GT9 may be connected to the gate low voltage line VGLL to receive the second gate low voltage VGL2.

Each of the first, second, fourth to sixth, and eighth gate transistors GT1, GT2, GT4, GT5, GT6, and GT8 may include a silicon-based active layer. For example, each of the first, second, fourth to sixth, and eighth gate transistors GT1, GT2, GT4, GT5, GT6, and GT8 may include an active layer made of low temperature polycrystalline silicon (LTPS). The active layer made of low temperature polycrystalline silicon may have high electron mobility and excellent turn-on characteristics. Accordingly, the stage STG may be driven stably and efficiently by including the transistors having the excellent turn-on characteristics.

Each of the first, second, fourth to sixth, and eighth gate transistors GT1, GT2, GT4, GT5, GT6, and GT8 may be a P-type transistor. For example, each of the first, second, fourth to sixth, and eighth gate transistors GT1, GT2, GT4, GT5, GT6, and GT8 may output a current introduced into the first electrode to the second electrode based on a gate low voltage applied to the gate electrode.

Each of the third, seventh, and ninth gate transistors GT3, GT7, and GT9 may include an oxide-based semiconductor region. For example, each of the third, seventh, and ninth gate transistors GT3, GT7, and GT9 may have a coplanar structure in which the gate electrode is disposed above the oxide-based semiconductor region. The transistor having the coplanar structure may have excellent leakage current characteristics and may be driven at a low frequency to reduce power consumption. Accordingly, the stage STG may prevent a leakage current from flowing and stably maintain a voltage inside the stage STG, by including the third, seventh, and ninth gate transistors GT3, GT7, and GT9 that have the excellent leakage current characteristics.

Each of the third, seventh, and ninth gate transistors GT3, GT7, and GT9 may be an N-type transistor. For example, each of the third, seventh, and ninth gate transistors GT3, GT7, and GT9 may output a current introduced into the first electrode to the second electrode based on a gate high voltage applied to the gate electrode.

The first gate capacitor GC1 may be connected between the third stage node GN3 and the output node OUT. Accordingly, the first gate capacitor GCI may maintain a potential difference between the third stage node GN3 and the output node OUT.

The second gate capacitor GC2 may be connected between the first gate high voltage VGH1 and the second stage node GN2. Accordingly, the second gate capacitor GC2 may maintain a potential difference between the first gate high voltage VGH1 and the second stage node GN2.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a light emitting element disposed on a substrate;
a first transistor configured to control a driving current flowing to a first node that is a first electrode of the light emitting element;
a second transistor configured to initialize the first node to a first initialization voltage based on a first gate signal having a first gate low voltage; and
a gate low voltage line configured to supply a second gate low voltage lower than the first gate low voltage to a bias electrode of the second transistor.

2. The display device of claim 1, further comprising:
a third transistor configured to supply a data voltage to a second node based on a second gate signal, the second node being a first electrode of the first transistor;
a fourth transistor electrically connecting a third node and a fourth node to each other based on a third gate signal, the third node being a second electrode of the first transistor and the fourth node being a gate electrode of the first transistor; and
a fifth transistor configured to initialize the fourth node to a second initialization voltage based on a fourth gate signal.

3. The display device of claim 2, further comprising:
a driving voltage line configured to supply a driving voltage;
a sixth transistor electrically connecting the driving voltage line and the second node to each other based on an emission signal; and
a seventh transistor electrically connecting the third node and the first node to each other based on the emission signal.

4. The display device of claim 3, wherein the driving voltage line and the gate low voltage line are disposed at a lower layer of a semiconductor region of the second transistor.

5. The display device of claim 3, further comprising:
a bottom metal layer disposed on the substrate and including the driving voltage line and the gate low voltage line;
a first active layer disposed on the bottom metal layer and including semiconductor regions of the first and second transistors;
a first gate layer disposed on the first active layer and including gate electrodes of the first and second transistors;
a second active layer disposed on the first gate layer and including a semiconductor region of the fourth transistor; and
a second gate layer disposed on the second active layer and including a gate electrode of the fourth transistor.

6. The display device of claim 3, further comprising an eighth transistor configured to supply a bias voltage to the second node based on the first gate signal.

7. The display device of claim 2, wherein the fourth transistor and the fifth transistor each include an oxide-based semiconductor region, and the second transistor includes a silicon-based semiconductor region.

8. The display device of claim 2, wherein the second transistor, the fourth transistor, and the fifth transistor each include a silicon-based semiconductor region, and
the gate low voltage line is configured to supply the second gate low voltage to a bias electrode of the fifth transistor.

9. The display device of claim 2, further comprising a plurality of stages configured to supply the first to fourth gate signals,
wherein the gate low voltage line is configured to supply the second gate low voltage to the plurality of stages.

10. The display device of claim 2, further comprising a plurality of stages configured to supply the first to fourth gate signals,
wherein the gate low voltage line is insulated from the plurality of stages.

11. A display device comprising:
a driving voltage line disposed on a substrate;
a first transistor disposed on the driving voltage line;
a light emitting element configured to receive a driving current flowing through the first transistor;
a second transistor configured to initialize a first node to a first initialization voltage based on a first gate signal, the first node being a first electrode of the light emitting element; and
a gate low voltage line disposed at a same layer as the driving voltage line and electrically connected to a bias electrode of the second transistor.

12. The display device of claim 11, wherein a low level of the first gate signal corresponds to a first gate low voltage, and the gate low voltage line is configured to supply a second gate low voltage lower than the first gate low voltage.

13. The display device of claim 11, further comprising:
a third transistor configured to supply a data voltage to a second node based on a second gate signal, the second node being a first electrode of the first transistor;
a fourth transistor electrically connecting a third node and a fourth node to each other based on a third gate signal, the third node being a second electrode of the first transistor and the fourth node being a gate electrode of the first transistor; and
a fifth transistor configured to initialize the fourth node to a second initialization voltage based on a fourth gate signal.

14. The display device of claim 13, further comprising:
a sixth transistor electrically connecting the driving voltage line and the second node to each other based on an emission signal;
a seventh transistor electrically connecting the third node and the first node to each other based on the emission signal; and
an eighth transistor configured to supply a bias voltage to the second node based on the first gate signal.

15. The display device of claim 11, wherein the bias electrode of the second transistor corresponds to a portion of the gate low voltage line and overlaps a semiconductor region and a gate electrode of the second transistor in a plan view.

16. The display device of claim 13, further comprising:
a bottom metal layer including the driving voltage line and the gate low voltage line;
a first active layer disposed on the bottom metal layer and including semiconductor regions of the first and second transistors;
a first gate layer disposed on the first active layer and including gate electrodes of the first and second transistors;
a second active layer disposed on the first gate layer and including a semiconductor region of the fourth transistor; and
a second gate layer disposed on the second active layer and including a gate electrode of the fourth transistor.

17. The display device of claim 13, wherein the fifth transistor includes an oxide-based semiconductor region, and the second transistor includes a silicon-based semiconductor region.

18. The display device of claim 13, wherein the fifth transistor and the second transistor each include a silicon-based semiconductor region, and
the gate low voltage line is configured to supply the second gate low voltage to a bias electrode of the fifth transistor.

19. The display device of claim 13, further comprising a plurality of stages configured to supply the first to fourth gate signals,
wherein the gate low voltage line is electrically connected to the plurality of stages.

20. The display device of claim 13, further comprising a plurality of stages configured to supply the first to fourth gate signals,
wherein the gate low voltage line is insulated from the plurality of stages.

21. A display device comprising:
a light emitting element disposed on a substrate;
a first transistor configured to control a driving current flowing to the light emitting element;
a second transistor configured to initialize a gate electrode of the first transistor to a first initialization voltage based on a first gate signal having a first gate low voltage; and
a gate low voltage line configured to supply a second gate low voltage lower than the first gate low voltage to a bias electrode of the second transistor.
